(19) United States
(12) Patent Application Publication
(10) Pub. No.: US 2017/0226658 A1
(43) Pub. Date: Aug. 10, 2017

(54) APPARATUS FOR MANUFACTURING SiC SINGLE CRYSTAL AND METHOD OF MANUFACTURING SiC SINGLE CRYSTAL

(71) Applicants: NIPPON STEEL & SUMITOMO METAL CORPORATION, Tokyo (JP); TOYOTA JIDOSHA KABUSHIKI KAISHA, Aichi (JP)

(72) Inventors: Yutaka KISHIDA, Chiba-shi, Chiba (JP); Kazuhito KAMEI, Kitakyushu-shi, Fukuoka (JP); Hironori DAIKOKU, Susono-shi, Shizuoka (JP); Masayoshi DOI, Nagoya-shi, Aichi (JP)

(73) Assignees: Nippon Steel & Sumitomo Metal Corporation, Tokyo (JP); Toyota Jidosha Kabushiki Kaisha, Aichi (JP)

(21) Appl. No.: 15/515,175

(22) PCT Filed: Oct. 7, 2015
(86) PCT No.: PCT/JP2015/078517

§ 371 Date: Mar. 29, 2017

(30) Foreign Application Priority Data
Oct. 10, 2014 (JP) 2014-208459

(51) Int. Cl. C30B 15/14; C30B 29/36; C30B 15/30; C30B 17/00; C30B 15/20

(52) U.S. Cl. CPC C30B 15/14; C30B 17/00; C30B 15/20; C30B 15/30; C30B 29/36; C30B 15/305

(57) ABSTRACT

A method and apparatus for manufacturing an SiC single crystal includes a graphite crucible for receiving an SiC solution with first and second induction heating coils wound around it. The first induction heating coil is located higher than the surface of the SiC solution. The second induction heating coil is located lower than the first induction heating coil. A power supply supplies a first alternating current to the first induction heating coil and supplies, to the second induction heating coil, a second alternating current having the same frequency as the first alternating current and flowing in the direction opposite to that of the first alternating current. The distance between the surface of the SiC solution and the position in the portion of the side wall of the crucible in contact with the SiC solution with the strength of a magnetic field at its maximum satisfies a predetermined equation.

### TECHNICAL FIELD

The present invention relates to an apparatus for manufacturing an SiC single crystal and a method of manufacturing an SiC single crystal, and more particularly to an apparatus for manufacturing an SiC single crystal used in connection with the solution growth method and a method of manufacturing an SiC single crystal by the solution growth method.

### BACKGROUND ART

One method of manufacturing silicon carbide (SiC) is the solution growth method. In the solution growth method, a seed crystal made of an SiC single crystal is brought into contact with an SiC solution. Portions of the SiC solution that are located close to the seed crystal are supercooled to cause an SiC single crystal to grow on the seed crystal.

One technique of the solution growth method is top-seeded solution growth (TSSG). An apparatus for manufacturing SiC single crystals used in connection with TSSG includes, for example, a seed shaft, a crucible made of graphite, an induction heating coil disposed around the crucible, and a power supply for supplying alternating current to the induction heating coil. As alternating current is supplied to the induction heating coil, the crucible is inductively heated. As the crucible is inductively heated, the Si material received by the crucible melts, producing a melt. As carbon (C) in the crucible dissolves in the melt, an SiC solution is produced. An SiC seed crystal attached to the bottom end of the seed shaft is brought into contact with the SiC solution to cause an SiC single crystal to grow on the SiC seed crystal.

The SiC solution is electrically conductive. Thus, when the crucible is inductively heated, the SiC solution is inductively stirred by Lorentz forces. This facilitates supplying of carbon from the crucible to the crystal growth interface.

The solution growth method produces an SiC single crystal with lower defect density and thus higher quality than the sublimation-recrystallization method does. One of the reasons for this is that step-flow growth converts threading dislocations into basal-plane defects.

### DISCLOSURE OF THE INVENTION

If SiC solution near the crystal growth interface flows in the same direction as the step-flow direction, this may lead to the meandering of steps or to different step distances. This may disturb the step structure. This in turn may generate new crystal defects or make it difficult to remove threading dislocations. Thus, in order to provide an SiC single crystal with fewer defects, it is desirable that the step-flow direction be opposite to the direction in which SiC solution flows near the crystal growth interface.

An object of the present invention is to provide an apparatus for manufacturing an SiC single crystal and a method of manufacturing an SiC single crystal where the step-flow direction is opposite to the direction in which SiC solution flows near the crystal growth interface.

The inventors of the present application did extensive research to find a way to achieve this object. They obtained the following findings.

The step-flow direction on the crystal growth interface is determined by the shape of the crystal growth interface. FIG. 7 schematically shows an SiC single crystal 32 growing on an SiC seed crystal 30 attached to the bottom end of the seed shaft 28A. If, as shown in FIG. 7, the crystal growth interface protrudes downward, then, the step-flow direction is from the center of the crystal growth interface toward the periphery.

In TSSG, heat of the crucible that has been inductively heated is transferred to the seed shaft through the SiC solution and seed crystal. The crystal growth interface is perpendicular to this route of heat transfer. That is, if an SiC single crystal is produced by TSSG, the crystal growth interface protrudes downward (hereinafter referred to as “downward-protruding”), as shown in FIG. 7. Accordingly, it is preferable that SiC solution flows from the crucible (more specifically, side wall) toward the seed crystal.

To achieve such a flow of SiC solution, Lorentz forces generated when the crucible is inductively heated may be used to electromagnetically stir the SiC solution. However, it is not easy to realize a flow of SiC solution from the crucible toward the seed crystal. This point will be explained below.

FIG. 8A shows a simulation result showing a distribution of lines of magnetic force generated when the crucible is inductively heated. FIG. 8B is a simulation result showing how SiC solution flows when the lines of magnetic force shown in FIG. 8A have been generated. The conditions for the simulations will be described with reference to FIG. 9.

The crucible 12 was made of graphite. The outer radius of the crucible 12, R12, was 58 mm. The inner radius of the crucible 12, R22, was 50 mm. The height of the crucible 12, H12, was 68 mm. The depth of the crucible 12, D12, was 60 mm. The bottom of the crucible 12 was rounded with a radius of 10 mm. The wall thickness of the crucible 12, T12, was 8 mm. The depth of the SiC solution 14 received by the crucible 12, D22, was 40 mm.

The induction heating coil 16 was a solenoid coil made of a copper pipe that is spirally wound. The induction heating coil 16 was positioned to be coaxial with the crucible 12. The inner radius of the induction heating coil 16, R32, was 120 mm. The winding number of the induction heating coil 16 was twelve (12). The distance between the top and bottom ends of the induction heating coil 16, H22, was 300 mm. The distance between the top end of the induction heating coil 16 and the top end of the crucible 12, H32, was 150 mm.

The seed shaft 28A was made of graphite. The outer radius of the seed shaft 28A was 25 mm. The length of the seed shaft 28A was 270 mm.

Referring to FIG. 8A, as alternating current flows through the induction heating coil 16, lines of magnetic force 18 are generated. The SiC solution 14 is electrically conductive. Thus, the lines of magnetic force 18 do not penetrate deep into the SiC solution 14. Portions of the lines of magnetic force 18 that are located in the portions of the side wall 12A of the crucible 12 that are in contact with the SiC solution 14 are separated from each other by smaller distances. That is, portions of the magnetic field generated during induction heating of the crucible 12 that are located in the portions of the side wall 12A in contact with the SiC solution 14 are stronger than other portions of the magnetic field. The position at which the strength of magnetic field is at its strongest, MP, is located within the portions of the side wall 12A that are in contact with the SiC solution 14.

The polarity of a rotation field (i.e. direction of rotation) of Lorentz forces acting on the SiC solution 14 is opposite to that of another rotation field that is located on the other side of a plane containing the position MP. Thus, as shown in FIG. 8B, the SiC solution 14 forms two eddies 14A and 14B, an upper one and a lower one, that have opposite directions of rotation. The lower eddy 14A, near its border with the upper eddy 14A, has a flow inward with respect to the crucible 12. The upper eddy 14B, near the bottom end of the seed shaft 20, that is, near the seed crystal attached to the bottom end of the seed shaft 20, flows outward with respect to the crucible 12. In this case, the flow of the SiC solution 14 at the downward-protruding crystal growth interface is the same as the step-flow direction.

From the simulation result shown in FIG. 5B, it can be found that, to achieve the intended flow of SiC solution 14, the upper eddy 14B may be made smaller and the lower eddy 14A may be made larger. In view of this, the inventors of the present application attempted the approach of weakening the magnetic field near the surface of the SiC solution 14 to weaken Lorentz forces that form the upper eddy 14B. More specifically, for example, they examined the approach of moving the induction heating coil downward or the approach of making the winding diameter of the induction heating coil at its upper end larger than the winding diameter at the lower end. However, it was found that, with each of these approaches, weakening the magnetic field near the solution surface moves the position MP downward. Further, the inventors examined the approach of changing the frequency of alternating current, but were unable to make the upper eddy 14B smaller and the lower eddy 14A larger.

Under these circumstances, the inventors of the present application focused on the position MP and did further research. They obtained a new finding that the intended flow of the SiC solution 14 can be achieved if the distance between the surface of the SiC solution 14 and the position MP is within a predetermined range. The present invention was made based on this new finding.

A manufacturing apparatus in an embodiment of the present invention is an apparatus for manufacturing an SiC single crystal by the solution growth method. The manufacturing apparatus includes a crucible, a seed shaft, a first induction heating coil, a second induction heating coil, and a power supply. The crucible is used to receive an SiC solution. The crucible includes a side wall that is in contact with the SiC solution when the SiC solution is received in the crucible. The crucible is made of graphite. An SiC seed crystal is attached to a bottom end of the seed shaft. When the SiC single crystal is attached to the seed shaft, the seed shaft is capable of bringing the SiC seed crystal into contact with the SiC solution. The first induction heating coil is disposed around the crucible. When the SiC solution is received in the crucible, the first induction heating coil is located higher than a surface of the SiC solution. The second induction heating coil is disposed around the crucible. The second induction heating coil is located lower than the first induction heating coil. The power supply supplies a first alternating current to the first induction heating coil. The power supply supplies a second alternating current to the second induction heating coil. The second alternating current has the same frequency as the first alternating current and flows in the direction opposite to that of the first alternating current. D satisfies the following equation, Equation (1), where D is the distance between the surface of the SiC solution and the position in a portion of the side wall in contact with the SiC solution at which the strength of a magnetic field generated as the power supply supplies the first alternating current to the first induction heating coil and supplies the second alternating current to the second induction heating coil is at its maximum:

D<2dₘ (1),

where dₘ satisfies the following equation, Equation (2):

[Formula 1]

$${d}_{m} = \sqrt{\frac{{ρ}_{m}}{π f {μ}_{m}}} \qquad ( 2 )$$

where ρₘ is the electric resistivity of the SiC solution,

is the ratio of the circumference of a circle to its diameter,

f is the frequency of the first and second alternating currents, and

μm is the magnetic permeability of the SiC solution.

In the above-described manufacturing apparatus, a cusped magnetic field is formed that has a cusp above the surface of the SiC solution (i.e. solution surface). If such a cusped magnetic field is formed and the distance D satisfies Equation (1), upper and lower eddies are formed in the SiC solution where the upper eddy is located in a small region defined by the solution surface of the SiC solution and the level at a distance therefrom of 2dₘ. That is, a large velocity gradient in the flow of the SiC solution occurs in this small region. The viscous force acting on the SiC solution is proportional to velocity gradient. Thus, a strong viscous force acts on the upper eddy. As a result, the upper eddy does not spread toward the SiC seed crystal, while the lower eddy is dominant in the overall flow of the SiC solution. As a result, a flow in the direction opposite to the step-flow direction is formed near the crystal growth interface of the SiC single crystal.

The position with the maximum magnetic field strength is the position at which the strength of a magnetic field affecting the flow of the SiC solution is at its maximum. Thus, for example, a position that has a larger magnetic field strength than the above-discussed position may be present outside the crucible.

The position with the maximum magnetic field strength may be located, for example, on the inner periphery of the side wall, or within the side wall.

### BRIEF DESCRIPTION OF THE DRAWINGS

FIG. 1 is a schematic view of a manufacturing apparatus in an embodiment of the present invention.

FIG. 2 is a conceptual view showing the distribution of lines of magnetic force generated when the crucible is inductively heated and two eddies generated in the SiC solution.

FIG. 3 illustrates the conditions for the simulations.

FIG. 4A shows a simulation result showing the distribution of lines of magnetic forces generated when the crucible is inductively heated.

FIG. 4B shows a simulation result showing the flow of the SiC solution occurring when the lines of magnetic force shown in FIG. 4A are present.

FIG. 5 is a schematic view of a crucible in an Example Application 1.

FIG. 6 is a schematic view of a crucible in an Example Application 2.

FIG. 7 is a schematic view of an SiC single crystal formed on a seed crystal and having a crystal growth interface protruding downward.

FIG. 8A shows a simulation result showing the distribution of lines of magnetic force generated when the crucible is inductively heated.

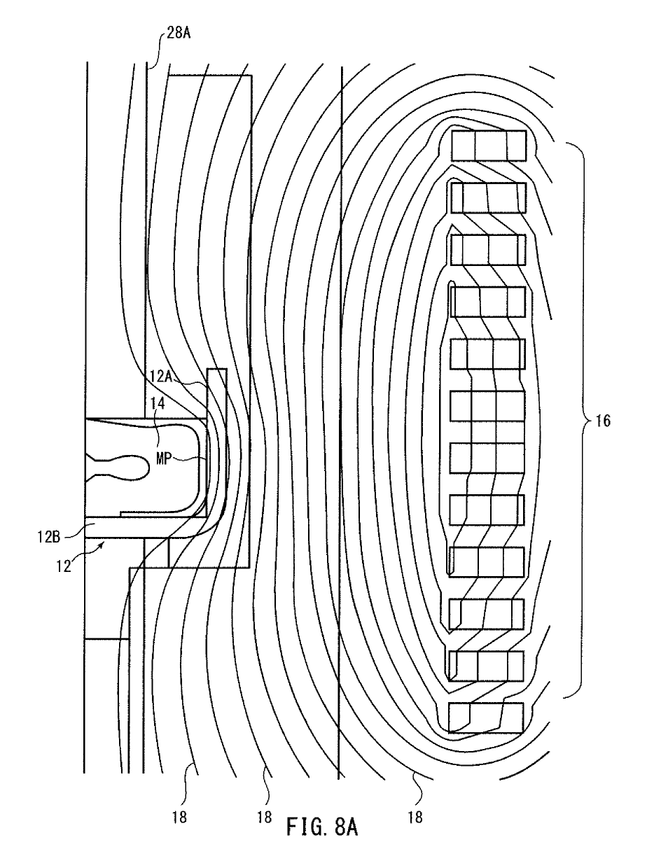

FIG. 8B shows a simulation result showing the flow of the SiC solution occurring when the lines of magnetic force shown in FIG. 8A have been generated.

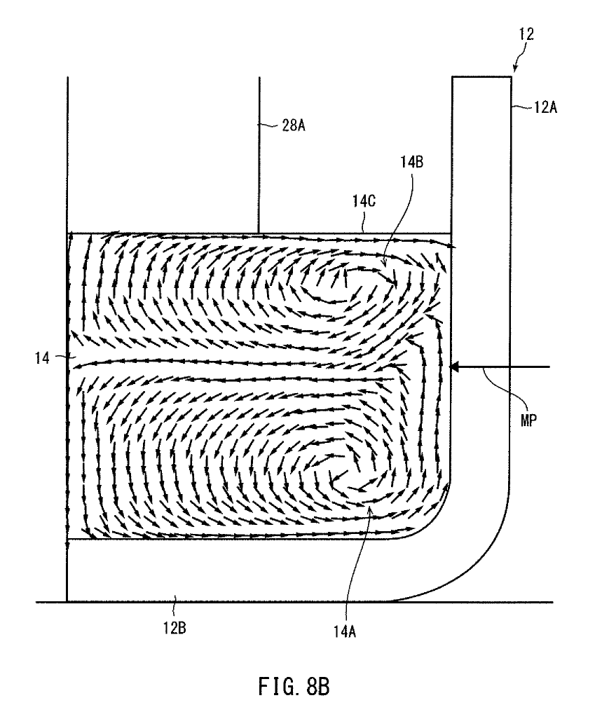

FIG. 9 illustrates the conditions for the simulations.

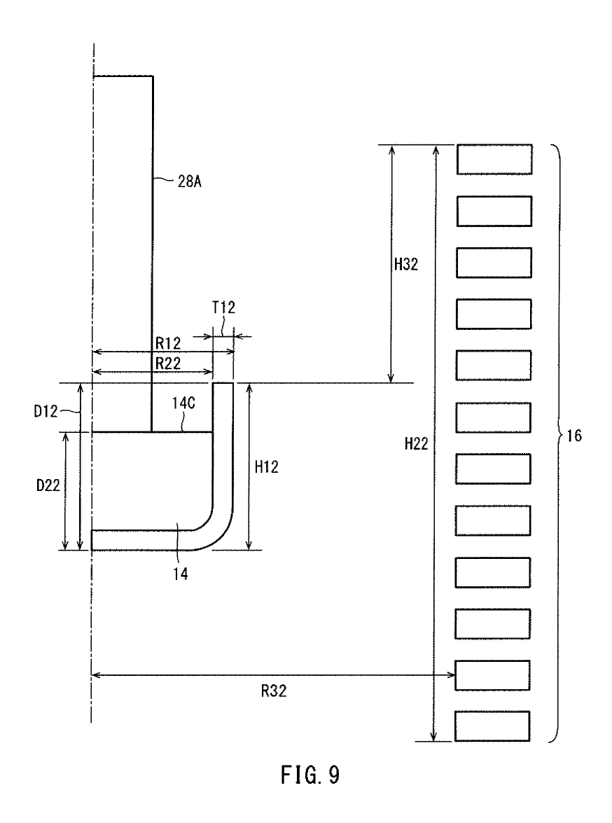

### EMBODIMENTS FOR CARRYING OUT THE INVENTION

Embodiments of the present invention will now be described with reference to the drawings. The same or corresponding parts in the drawings are labeled with the same characters and their description will not be repeated.

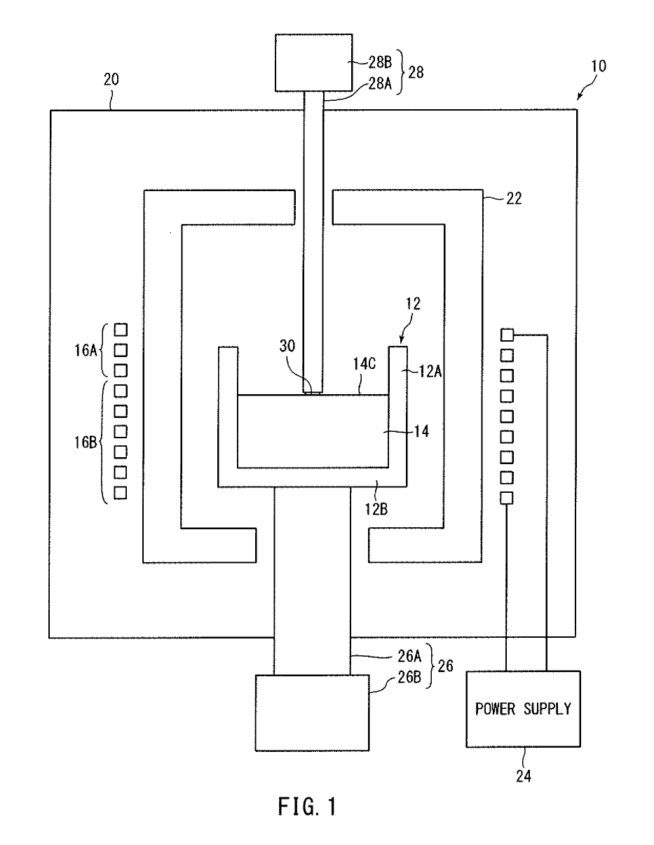

FIG. 1 is a schematic view of a manufacturing apparatus 10 that can be used for the method of manufacturing an SiC single crystal according to an embodiment of the present invention. The manufacturing apparatus 10 shown in FIG. 1 is an example manufacturing apparatus that can be used for the solution growth method (more specifically, TSSG). The manufacturing apparatus that can be used for the solution growth method is not limited to the manufacturing apparatus 10 shown in FIG. 1.

The manufacturing apparatus 10 includes a chamber 20, a crucible 12, an insulating member 22, a first induction heating coil 16A, a second induction heating coil 16B, a power supply 24, a rotating device 26, and a lifting device 28.

The chamber 20 houses the crucible 12. The chamber 20 is cooled during manufacture of an SiC single crystal.

The crucible 12 is made of graphite and receives an SiC solution 14. The SiC solution 14 is a melt of Si or an Si alloy in which carbon (C) has dissolved. The crucible 12 includes a side wall 12A and a bottom wall 12B. The bottom edge of the side wall 12A is integrally formed with the bottom wall 12B. Part of the inner periphery of the side wall 12A is in contact with the SiC solution 14. The side wall 12A has a thickness that is generally constant along the height direction of the crucible 12. The side wall 12A is cylindrical in shape.

The insulating member 22 is made of an insulator and surrounds the crucible 12.

The first induction heating coil 16A is disposed around the side wall 12A. The second induction heating coil 16B is located below the first induction heating coil 16A, and is disposed around the side wall 12A. The second induction heating coil 16B is wound in the direction opposite to that in which the first induction heating coil 16A is wound. The second induction heating coil 16B has an inner diameter equal to the inner diameter of the first induction heating coil 16A. The second induction heating coil 16B has a height (i.e. length as measured in the top-to-bottom direction in FIG. 1) that is larger than that of the first induction heating coil 16A. The winding number of the second induction heating coil 16B is greater than the winding number of the first induction heating coil 16A. Preferably, the winding number of the second induction heating coil 16B is twice the winding number of the first induction heating coil 16A or greater. The top end of the second induction heating coil 16B is connected with the bottom end of the first induction heating coil 16A.

The top end of the first induction heating coil 16A and the bottom end of the second induction heating coil 16B are connected to the power supply 24. The power supply 24 supplies alternating current to the first and second induction heating coils 16A and 16B.

The rotating device 26 includes a rotating shaft 26A and a drive source 26B.

The rotating shaft 26A extends in the height direction of the chamber 20 (i.e. top-to-bottom direction in FIG. 1). The top end of the rotating shaft 26A is located inside the insulating member 22. The crucible 12 is positioned on the top end of the rotating shaft 26A. The bottom end of the rotating shaft 26A is located outside the chamber 20.

The drive source 26B is located below the chamber 20. The drive source 26B is coupled to the rotating shaft 26A. The drive source 26B rotates the rotating shaft 26A about the central axis of the rotating shaft 26A.

The lifting device 28 includes a seed shaft 28A and a drive source 28B.

The seed shaft 28A extends in the height direction of the chamber 20. The top end of the seed shaft 28A is located outside the chamber 20. The SiC seed crystal 30 is attached to the bottom-end surface of the seed shaft 28A.

The SiC seed crystal 30 is made of an SiC single crystal. The crystal structure of the SiC seed crystal 30 is 4H polytype. The crystal growth surface of the SiC seed crystal 30 may be the C-face or Si-face. The off angle of the crystal growth surface is in the range of 1° to 4°, for example. Off angle of the crystal growth surface means the angle formed by a straight line extending in a direction perpendicular to the crystal growth surface and a straight line extending in the direction of the c-axis.

The drive source 28B is located above the chamber 20. The drive source 28B is coupled to the seed shaft 28A. The drive source 28B lifts and lowers the seed shaft 28A. Further, the drive source 28B rotates the seed shaft 28A about the central axis of the seed shaft 28A.

A method of manufacturing an SiC single crystal using the manufacturing apparatus 10 will now be described. First, an SiC seed crystal 30 is attached to the bottom-end surface of the seed shaft 28A.

Next, the crucible 12 is positioned on the rotating shaft 26A in the chamber 20. The crucible 12 contains a raw material of the SiC solution 14. The raw material may be Si alone, for example, or a mixture of Si and another metal element. The metal element may be, for example, titanium (Ti), manganese (Mn), chromium (Cr), cobalt (Co), vanadium (V), iron (Fe), or other elements. The form of the raw material may be, for example, a plurality of masses or powder.

Next, the SiC solution 14 is produced. First, the chamber 20 is filled with inert gas. Then, the first and second induction heating coils 16A and 1813 inductively heat the crucible 12. As the crucible 12 is inductively heated, the raw material for the SiC solution 14 in the crucible 12 is heated to its melting point or higher temperatures. Heating the crucible 12 causes carbon in the crucible 12 to dissolve in the melt. Thus, the SiC solution 14 is produced. When carbon continues to dissolve in the melt, the carbon concentration in the SiC solution 14 rises to near the saturation level.

Next, the drive source 28B lowers the seed shaft 28A to allow the crystal growth surface of the SiC seed crystal 30 to contact the SiC solution 14. At this step, the SiC seed crystal 30 may be immersed in the SiC solution 14.

After the crystal growth surface of the SiC seed crystal 30 contacts the SiC solution 14, the first and second induction heating coils 16A and 1613 continue to inductively heat the crucible 12, thereby keeping the SiC solution 14 at a crystal growth temperature. The crystal growth temperature is in the range of 1650 to 1850° C., and more preferably in the range of 1700 to 1800° C.

Further, portions of the SiC solution 14 that are located near the SiC seed crystal 30 are supercooled to supersaturate them with SiC. During this step, the temperature gradient in portions of the SiC solution 14 that are located directly below the SiC seed crystal 30 is higher than 0° C/cm and not higher than 20° C./cm. Preferably, it is not lower than 5° C./cm and not higher than 15° C./cm. More preferably, it is not lower than 7° C. and not higher than 11° C.

Any method may be used for supercooling portions of the SiC solution 14 near the SiC seed crystal 30. For example, the supply of electric power to the first and second induction heating coils 16A and 16B may be controlled to make the temperature of portions of the SiC solution 14 near the SiC seed crystal 30 lower than the temperature of other portions. Alternatively, portions of the SiC solution 14 near the SiC seed crystal 30 may be cooled by a coolant. More specifically, a coolant may be circulated through the inside of the seed shaft 28A. The coolant may be, for example, an inert gas such as helium (He) or argon (Ar). Circulating the coolant through the seed shaft 28A cools the SiC seed crystal 30. As the SiC seed crystal 30 is cooled, portions of the SiC solution 14 near the SiC seed crystal 30 are cooled, as well.

With portions of the SiC solution 14 near the SiC seed crystal 30 kept supersaturated with SiC, the SiC seed crystal 30 and SiC solution 14 (i.e. crucible 12) are rotated. Rotating the seed shaft 28A rotates the SiC seed crystal 30. Rotating the rotating shaft 26A rotates the crucible 12. The direction of rotation of the SiC seed crystal 30 may be opposite to or the same as the direction of rotation of the crucible 12. The rate of rotation may be constant or may vary The seed shaft 28A is gradually lifted while rotating. During this time, an SiC single crystal grows on the crystal growth surface of the SiC seed crystal 30 that is in contact with the SiC solution 14. Alternatively, the seed shaft 28A may be rotated without being lifted, or may be neither lifted nor rotated.

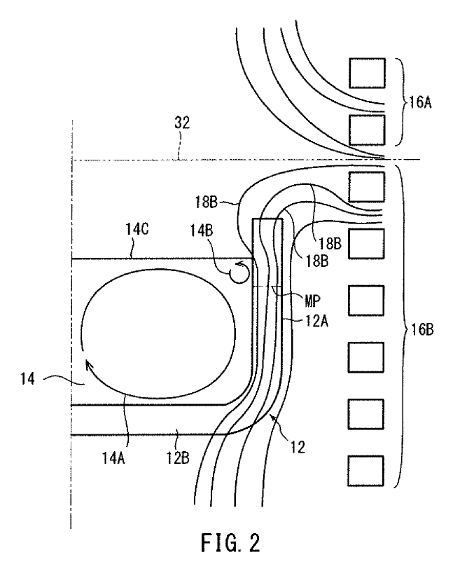

While an SiC single crystal is manufactured by the above-discussed method, alternating current flows through the first and second induction heating coils 16A and 16B. The direction in which the first induction heating coil 16A is wound is opposite to the direction in which the second induction heating coil 16B is wound. Thus, alternating current flowing through the first induction heating coil 16A (hereinafter referred to as first alternating current), as compared with alternating current flowing through the second induction heating coil 16B (hereinafter referred to as second alternating current), has the same frequency and the same effective value but flows in the opposite direction. As a result, as shown in FIG. 2, two magnetic fields, i.e. an upper one and a lower one, are formed. The upper magnetic field is formed as the first alternating current flows. The lower magnetic field is formed as the second alternating current flows. Due to the electromagnetic principle of superposition, a neutral plane 32 appears between the first and second induction heating coils 16A and 16B, formed as the upper and lower magnetic fields cancel each other and having a magnetic field strength of zero. The neutral plane 32 is located higher than the solution surface 14C of the SiC solution 14.

The SiC solution 14 is electrically conductive. As such, as shown in FIG. 2, the lines of magnetic force 18B generated as the second alternating current flows do not penetrate deep into the inside of the SiC solution 14. Portions of the lines of magnetic force 18B located in portions of the side wall 12A that are in contact with the SiC solution 14 are separated by smaller distances. That is, portions of the lower magnetic field located in portions of the side wall 12A that are in contact with the SiC solution 14 are stronger than other portions of this magnetic field. The position MP at which the magnetic field strength is at its strongest is located within the portions of the side wall 12A in contact with the SiC solution 14. The magnetic field that has the largest strength at the position MP is the magnetic field that affects the flow of the SiC solution 14, i.e. the magnetic field formed as the second alternating current flows.

The polarity of a rotation field (i.e. direction of rotation) of Lorentz forces acting on the SiC solution 14 is opposite to that of the other rotation field located on the other side of a plane containing the position MP. Thus, the SiC solution 14 forms two eddies, i.e. an upper one and a lower one, that have opposite directions of rotation. The upper eddy, at the solution surface, flows outward with respect to the crucible 12. The lower eddy, at its border with the upper eddy, flows inward with respect to the crucible 12.

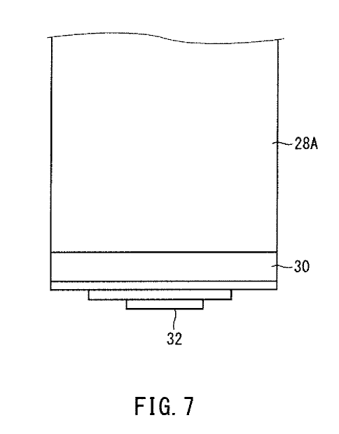

The manufacturing apparatus 10 is used to manufacture an SiC single crystal by TSSG. Thus, the SiC single crystal produced by the manufacturing apparatus 10 has a crystal growth interface protruding downward, as shown in FIG. 7. In view of this, when an SiC single crystal is to be manufactured by the manufacturing apparatus 10, a large lower eddy 14A is created and the upper eddy 14B is trapped near the solution surface 14C and side wall 12A, as shown in FIG. 2. This allows portions of the SiC solution 14 near the SiC seed crystal 30 to flow inward with respect to the crucible 12. As a result, the step-flow direction is opposite to the direction in which the SiC solution 14 flows near the crystal growth interface.

The upper eddy 14B is trapped in the above-described region if the distance D between the position MP and solution surface meets the following equation, Equation (1):

D<2dₘ (1),

where dₘ meets the following equation, Equation (2):

[Formula 2]

$${d}_{m} = \sqrt{\frac{{ρ}_{m}}{π f {μ}_{m}}} \qquad ( 2 )$$

where ρₘ is the electric resistivity of the SiC solution,
n is the ratio of the circumference of a circle to its diameter,
f is the frequency of the first and second alternating currents, and
μm is the magnetic permeability of the SiC solution.

The position of the neutral plane 32 (i.e. position as measured in the top-bottom direction) may be changed to change the distance D. Thus, it is important to decide where to position the neutral plane 32. The position of the neutral plane may be determined by a numerical electromagnetic field analysis which takes account of, for example, the positional relationship between the first and second induction heating coils 16A and 16B and crucible 12, the winding number of the first induction heating coil 16A and the winding number of the second induction heating coil 16B. The numerical electromagnetic field analysis may be performed using known analysis software. The numerical electromagnetic field analysis determines the position MP. If the position MP is determined, the distance D is determined. The positional relationship between the first and second induction heating coils 16A and 16B and crucible 12, the winding number of the first induction heating coil 16A, the winding number of the second induction heating coil 16B etc. are suitably determined taking account of the frequency of the first and second alternating currents such that the distance D meets Equation (1). When the position relationship is to be determined, the optimum-value seek function of the analysis software may be used, for example.

While the SiC single crystal is being produced, carbon in the crucible 12 dissolves in the SiC solution 14, thereby changing the volume of the crucible 12. This changes the position of the solution surface 14C of the SiC solution 14. To address the changes in the position of the solution surface 14C while the SiC single crystal is being produced, the first and second induction heating coils 16A and 16B may be movable relative to the crucible 12.

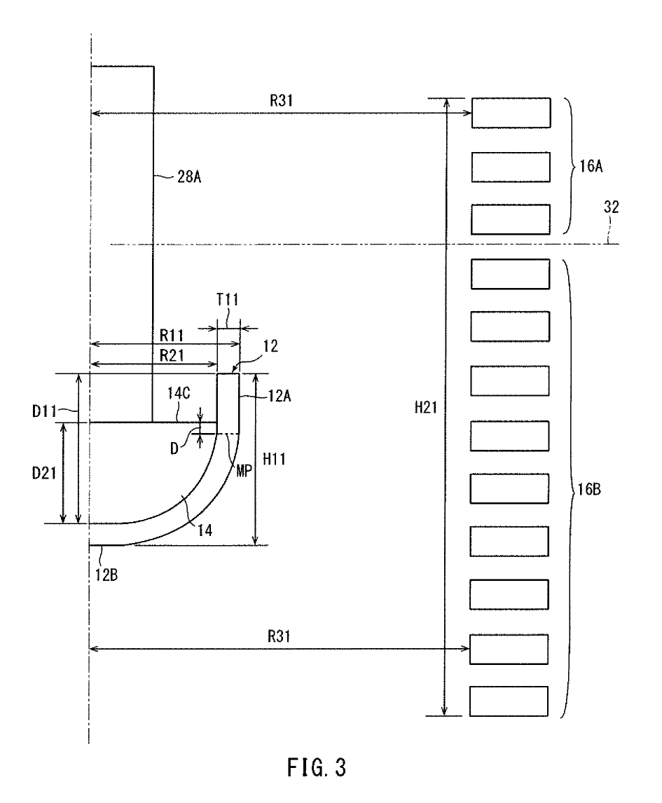

Simulations were made for the manufacturing apparatus 10. The conditions for the simulations will be described with reference to FIG. 3.

The crucible 12 was made of graphite. The outer radius of the crucible 12, R11, was 58 mm. The inner radius of the crucible 12, R21, was 50 mm. The height of the crucible 12, H11, was 68 mm. The depth of the crucible 12, D11, was 60 mm. The bottom of the crucible 12 was rounded with a radius of 30 mm. The wall thickness of the crucible 12, T11 was 8 mm. The depth of the SiC solution 14 received by the crucible 12, D21, wad 40 mm.

The first and second induction heating coils 16A and 16B were solenoid coils made of a copper pipe that was spirally wound. The first and second induction heating coils 16A and 16B were positioned to be coaxial with the crucible 12. The inner radius of the first and second induction heating coils 16A and 16B, R31, was 120 mm. The winding number of the first induction heating coil 16A was three (3). The winding number of the second induction heating coil 16B was nine (9). The distance between the top end of the first induction heating coil 16A and the bottom end of the second induction heating coil 16B, H21, was 300 mm.

The frequency of the first and second alternating currents was 5 kHz. dₘ was 6.4 mm.

The neutral plane 32 was positioned 30 mm above the solution surface 14C of the SiC solution 14. The distance D was 9.0 mm.

The seed shaft 28A was made of graphite. The outer radius of the seed shaft 28A was 25 mm. The length of the seed shaft 28A was 270 mm.

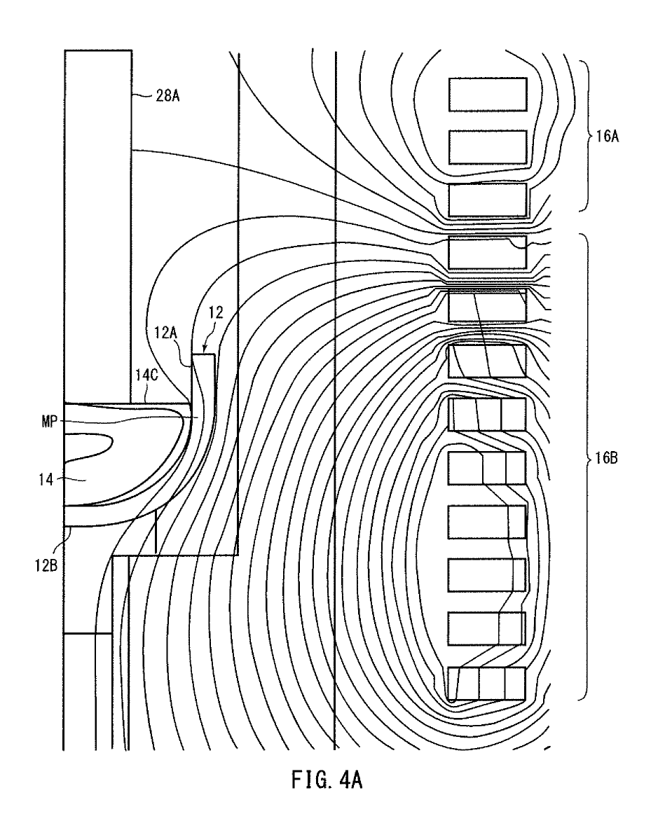

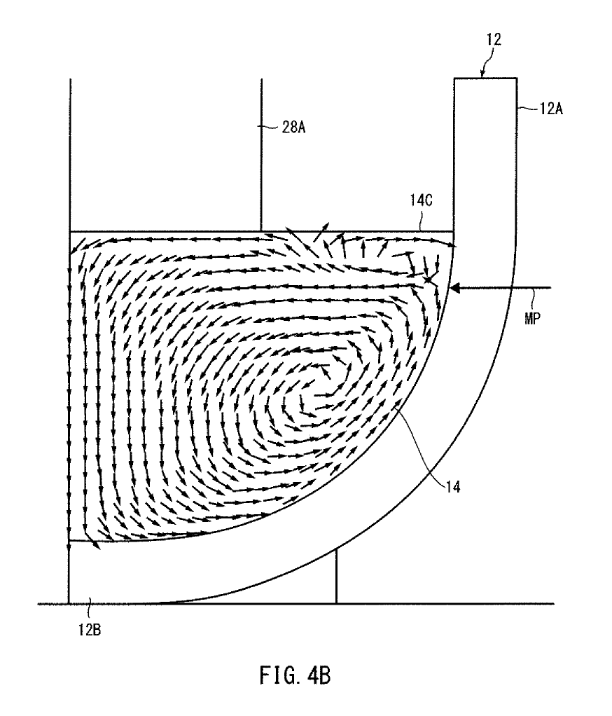

FIGS. 4A and 4B show results of the simulations under the above conditions. FIG. 4A shows a simulation result showing the distribution of lines of magnetic force generated when the crucible 12 is inductively heated. FIG. 4B shows a simulation result showing the flow of the SiC solution 14 occurring when the lines of magnetic force shown in FIG. 4A are present.

As shown in FIGS. 4A and 4B, if the distance D meets Equation (1), the upper eddy is trapped near the solution surface and side wall and the lower eddy is dominant in the overall flow of the SiC solution. As a result, a flow in the direction opposite to the step-flow direction was formed below the seed shaft, i.e. near the crystal growth interface of the SiC single crystal.

[Example Application 1 of Crucible]

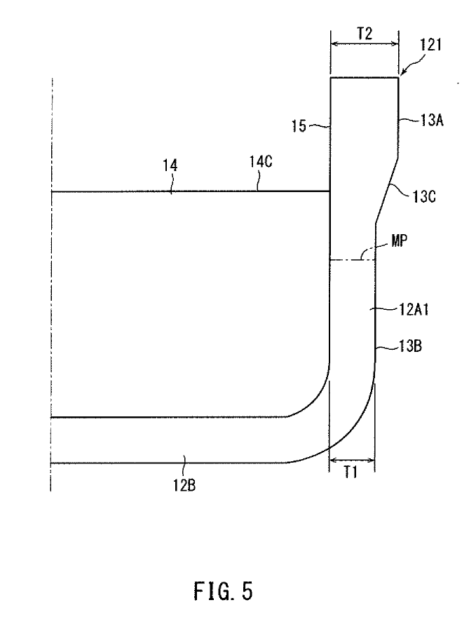

A crucible 121 according to Example Application 1 will be described with reference to FIG. 5. As compared with the crucible 12, the crucible 121 includes, instead of the side wall 12A, a side wall 12A1. The side wall 12A1 is cylindrical in shape. The side wall 12A1 includes a first outer periphery section 13A, a second outer periphery section 13B, a third outer periphery section 13C, and an inner periphery 15.

The first outer periphery section 13A is located higher than the solution surface 14C of the SiC solution 14. The first outer periphery section 13A has a diameter that is generally constant over the entire length as measured in the height direction.

The second outer periphery section 13B is located lower than the solution surface 14C. The second outer periphery section 13B has a smaller diameter than the first outer periphery section 13A. The second outer periphery section 13B has a diameter that is generally constant over the entire length as measured in the height direction.

The third outer periphery section 13C is located between the first and second outer periphery sections 13A and 13B to connect the first and second outer periphery sections 13A and 13B. The diameter of the third outer periphery section 13C gradually increases as it goes from the lower edge toward the upper edge. In other words, the third outer periphery section 13C is a slope.

The inner periphery 15 has a diameter that is generally constant over the entire length as measured in the height direction. As such, the portions of the side wall 12A1 that have the first outer periphery section 13A have a larger thickness than the portions that have the second outer periphery section 13B. The position MP is present within the portions of the side wall 12A1 that have the second outer periphery section 13B.

The thickness of the portions of the side wall 12A1 that have the second outer periphery section 13B, T1, and the thickness of the portions that have the first outer periphery section 13A, T2, meet the following equation, Equation (3):

T1<T2 (3).

Further, in the implementation shown in FIG. 5, the thickness T1 meets Equation (4) provided below, and the thickness T2 meets Equation (5) provided below:

T1<d_{c} (4), and

T2>d_{c} (5),

where d_{c} meets the following equation, Equation (6):

[Formula 3]

$${d}_{c} = \sqrt{\frac{{ρ}_{c}}{π f {μ}_{c}}} \qquad ( 6 )$$

where ρ_{c} is the electric resistivity of the crucible 121, and

μ_{c} is the magnetic permeability of the crucible 121.

If an SiC single crystal is manufactured using the crucible 121, the portions of the side wall 12A1 that have the thickness T1 shield against the magnetic field generated as the second alternating current flows (i.e. lower magnetic field). This reduces the strength of the portions of the lower magnetic field that are located higher than the solution surface 14C. As a result, the strength of the trapped upper eddy is reduced, making it easier for the lower eddy to dominate the overall flow of the SiC solution 14.

[Example Application 2 of Crucible]

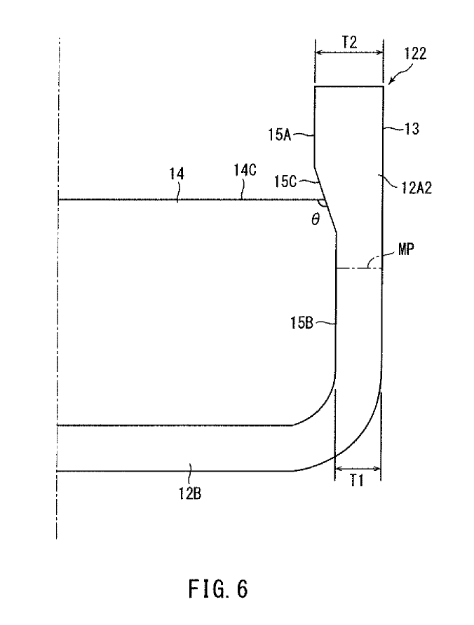

A crucible 122 according to Example Application 2 will be described with reference to FIG. 6. As compared with the crucible 12, the crucible 122 includes, instead of the side wall 12A, a side wall 12A2. The side wall 12A2 is cylindrical in shape. The side wall 12A2 includes a first inner periphery section 15A, a second inner periphery section 15B, a third inner periphery section 15C, and an outer periphery 13.

The first inner periphery section 15A is located higher than the solution surface 14C of the SiC solution 14. The first inner periphery section 15A has a diameter that is generally constant over the entire length as measured in the height direction.

The second inner periphery section 15B is located lower than the solution surface 14C. The second inner periphery section 15B has a larger diameter than the first inner periphery section 15A. The second inner periphery section 15B has a diameter that is generally constant over the entire length as measured in the height direction.

The third inner periphery section 15C is located between the first and second inner periphery sections 15A and 15B and connects the first and second periphery sections 15A and 15B. The diameter of the third inner periphery section 15C gradually increases as it goes from the lower edge toward the upper edge. In other words, the third inner periphery section 15C is a slope.

The outer periphery 13 has a diameter that is generally constant over the entire length as measured in the height direction. As such, the portions of the side wall 12A2 that have the first inner periphery section 15A have a larger thickness than the portions that have the second inner periphery section 15B. The position MP is present within the portions of the side wall 12A2 that have the second inner periphery section 15B.

The thickness of the portions of the side wall 12A2 that have the second inner periphery section 15B, T1, and the thickness of the portions that have the first inner periphery section 15A, T2, meet the following equation, Equation (3):

T1<T2 (3).

Further, in the implementation shown in FIG. 6, the thickness T1 meets Equation (4) provided below, and the thickness T2 meets Equation (5) provided below:

T1<d_{c} (4), and

T2>d_{c} (5),

where d_{c} meets the following equation, Equation (6):

[Formula 4]

$${d}_{c} = \sqrt{\frac{{ρ}_{c}}{π f {μ}_{c}}} \qquad ( 6 )$$

where ρ_{c} is the electric resistivity of the crucible 122, and

μ_{c} is the magnetic permeability of the crucible 122.

If an SiC single crystal is manufactured using the crucible 122, the portions of the side wall 12A2 that have the thickness T1 shield against the magnetic field generated as the second alternating current flows (i.e. lower magnetic field). This reduces the strength of the portions of the lower magnetic field that are located higher than the solution surface 14C. As a result, the strength of the trapped upper eddy is reduced, making it easier for the lower eddy to dominate the overall flow of the SiC solution 14.

If an SiC single crystal is manufactured using the crucible 122, the angle θ formed by the solution surface 14C and third inner periphery section 15C is obtuse, as shown in FIG. 6. This mitigates concentration of Lorentz forces generated in the SiC solution 14 in the outer periphery of the solution surface 14C, i.e. in and near the portions of the solution surface 14C that are in contact with the third inner periphery section 15C. This will reduce the strength of the upper eddy trapped as described above. The lower eddy is more likely to dominate the overall flow of the SiC solution 14.

Although embodiments of the present invention have been described in detail, these embodiments are merely illustrative and the present invention is not limited in any way to the above-described embodiments.

1. A method of manufacturing an SiC single crystal by a solution growth method, where an SiC seed crystal is brought into contact with an SiC solution received in a crucible to grow the SiC single crystal, the method comprising the steps of:
supplying a first alternating current to a first induction heating coil disposed around the crucible and located higher than a solution surface of the SiC solution, and supplying a second alternating current having the same frequency as the first alternating current and in a direction opposite to that of the first alternating current to a second induction heating coil disposed around the crucible and located lower than the first induction heating coil; and
bringing the SiC seed crystal into contact with the SiC solution, the SiC seed crystal being attached to a bottom end of a seed shaft,
wherein D satisfies the following equation, Equation (1), where D is the distance between the solution surface and the position in a portion of a side wall of the crucible in contact with the SiC solution at which the strength of magnetic field generated in the step of supplying the first and second alternating currents is at its maximum:
D<2dₘ (1),
where dₘ satisfies the following equation, Equation (2):
[Formula 1]
$${d}_{m} = \sqrt{\frac{{ρ}_{m}}{π f {μ}_{m}}} \qquad ( 2 )$$
where ρₘ is the electric resistivity of the SiC solution, π is the ratio of the circumference of a circle to its diameter, f is said frequency, and μₘ is the magnetic permeability of the SiC solution.

2. The manufacturing method according to claim 1, wherein T1 and T2 satisfy the following equation, Equation (3):
T1<T2 (3),
where T1 is the thickness of the side wall at said position and T2 is the maximum thickness of a portion of the side wall located higher than the solution surface.

3. The manufacturing method according to claim 2, wherein T1 satisfies Equation (4) indicated below and T2 satisfies Equation (5) indicated below:
T1<d_{c} (4), and
T2>d_{c} (5),
where d_{c} satisfies the following equation, Equation (6):
[Formula 2]
$${d}_{c} = \sqrt{\frac{{ρ}_{c}}{π f {μ}_{c}}} \qquad ( 6 )$$
where ρ_{c} is the electric resistivity of the crucible and μ_{c} is the magnetic permeability of the crucible.

4. The manufacturing method according to claim 2 or 3, wherein the side wall includes;
a first inner periphery section which is an inner periphery of a portion having a thickness of T1; and
a second inner periphery section which is an inner periphery of a portion having a thickness of T2,
wherein the first inner periphery section is located outward of the second inner periphery section as measured in a horizontal direction.

5. The manufacturing method according to claim 4, wherein the side wall further includes a sloped inner periphery connecting the first and second inner periphery sections.

6. An apparatus for manufacturing an SiC single crystal by a solution growth method, comprising:
a crucible made of graphite, the crucible including a side wall and capable of receiving an SiC solution;
a seed shaft having a bottom end to which an SiC seed crystal can be attached, the seed shaft being capable of bringing the SiC seed crystal into contact with the SiC solution;
a first induction heating coil disposed around the crucible, the first induction heating coil being located higher than a surface of the SiC solution when the SiC solution is received in the crucible;
a second induction heating coil disposed around the crucible and located lower than the first induction heating coil; and
a power supply for supplying a first alternating current to the first induction heating coil and supplying a second alternating current to the second induction heating coil, the second alternating current having the same frequency as the first alternating current and being in the direction opposite to that of the first alternating current,
wherein, when the SiC solution is received in the crucible, D satisfies the following equation, Equation (1):
D<2dₘ (1),
where D is the distance between the surface of the SiC solution and the position in a portion of the side wall in contact with the SiC solution at which the strength of a magnetic field generated as the power supply supplies the first alternating current to the first induction heating coil and supplies the second alternating current to the second induction heating coil is at its maximum, and dₘ satisfies the following equation, Equation (2):
[Formula 3]
$${d}_{m} = \sqrt{\frac{{ρ}_{m}}{π f {μ}_{m}}} \qquad ( 2 )$$
where ρₘ is the electric resistivity of the SiC solution, π is the ratio of the circumference of a circle to its diameter, f is said frequency, and μₘ is the magnetic permeability of the SiC solution.
